(19) United States
(12) Patent Application Publication
(10) Pub. No.: US 2014/0117538 A1
(43) Pub. Date: May 1, 2014

(54) PACKAGE STRUCTURE AND FABRICATION METHOD THEREOF

(71) Applicant: Siliconware Precision Industries Co., Ltd., Taichung (TW)

(72) Inventors: Kuang-Hsin Chen, Taichung Hsien (TW); Chun-Hung Lu, Taichung Hsien (TW)

(73) Assignee: SILICONWARE PRECISION INDUSTRIES CO., LTD., Taichung (TW)

(21) Appl. No.: 13/949,557

(22) Filed: Jul. 24, 2013

(30) Foreign Application Priority Data
Oct. 30, 2012 (TW) 101140058

(51) Int. Cl. H01L 23/498; H01L 21/50

(52) U.S. Cl. CPC H01L 23/49811; H01L 21/50
USPC 257/737; 438/106

(57) ABSTRACT

A fabrication method of a package structure is provided, which includes the steps of: providing an interposer having a plurality of recess holes; forming a conductive bump in a lower portion of each of the recess holes; forming a conductive through hole on the conductive bump in each of the recess holes; removing a portion of the interposer so as for the conductive bumps to protrude from the interposer; and mounting at least a first external element on the conductive bumps, thereby simplifying the fabrication process, shortening the process time and reducing the material cost.

### BACKGROUND OF THE INVENTION

1. Field of the Invention

The present invention relates to package structures, and more particularly, to a package structure having an interposer and a fabrication method thereof.

2. Description of Related Art

Flip-chip technologies facilitate to reduce chip packaging sizes and shorten signal transmission paths and therefore have been widely used for chip packaging. Various types of packages such as chip scale packages (CSPs), direct chip attached (DCA) packages and multi-chip module (MCM) packages can be achieved through flip-chip technologies.

In a flip-chip packaging process, a big CTE (Coefficient of Thermal Expansion) mismatch between a chip and a packaging substrate adversely affects the formation of joints between conductive bumps of the chip and contacts of the packaging substrate, thus easily resulting in delamination of the conductive bumps from the packaging substrate.

On the other hand, along with increased integration of integrated circuits, a CTE mismatch between a chip and a packaging substrate induces more thermal stresses and leads to more serious warpage, thereby reducing the product reliability and resulting in failure of a reliability test.

Conventionally, a plurality of chips are disposed on a packaging substrate in a 2D manner. Accordingly, when the number of the chips increases, the area of the packaging substrate must be increased, which, however, does not meet the demands for miniaturization and high functionality of electronic products.

Further, as the circuit density of semiconductor chips continuously increases, the pitch between the electrode pads of the semiconductor chips reaches the nanometer scale. On the other hand, the pitch between the contacts of the packaging substrates are only at the micrometer scale and does not match the nanometer scale of the pitch between the electrode pads of the semiconductor chips, thus adversely affecting the fabrication of electronic products.

To overcome the above-described drawbacks, an interposer made of a semiconductor material is provided, which has a first surface for bonding with a semiconductor chip and an opposite second surface for bonding with a packaging substrate. Since the interposer and the semiconductor chip are made of similar materials, the above-described drawbacks caused by a CTE mismatch can be effectively prevented. Further, the first surface of the interposer has a plurality of circuits formed thereon through a semiconductor wafer process. Since the electrode pads or circuits of the semiconductor chip are also fabricated through a semiconductor wafer process, a plurality of such semiconductor chips can be disposed on the first surface of the interposer without the need to increase the area of the interposer. Furthermore, the semiconductor chips can be disposed on the interposer in a stack manner so as to meet the demands for miniaturization and high functionality of electronic products.

FIG. 1 is a schematic cross-sectional view showing a conventional semiconductor package. Referring to FIG. 1, a silicon interposer 2 is disposed between a packaging substrate 9 and a semiconductor chip 8. A plurality of through silicon vias (TSVs) 21 are formed in the silicon interposer 2 and an RDL (redistribution layer) structure 22 is formed on one ends of the TSVs 21. The RDL structure 22 is electrically connected to the bonding pads 90 of the packaging substrate 9 through a plurality of conductive elements 23, and the TSVs 21 are electrically connected to the electrode pads 80 of the semiconductor chip 8 through a plurality of solder bumps 27′. Then, an encapsulant 7 is formed to encapsulate the semiconductor chip 8. In another embodiment, the RDL structure can be formed on the other ends of the TSVs 21 and electrically connected to the semiconductor chip 8.

Therefore, the packaging substrate 9 and the semiconductor chip 8 having a high circuit density are connected through the silicon interposer 2.

Since the CTE of the silicon interposer 2 is close to the CTE of the semiconductor chip 8, cracking of the solder bumps 27′ is prevented and the product reliability is improved.

Compared with a conventional flip-chip package, the semiconductor package 1 has reduced length and width. For example, a conventional flip-chip packaging substrate has a minimum line width 12 um and a minimum line pitch of 12 um. When the number of the electrode pads of the semiconductor chip increases, the line width/line pitch of the flip-chip packaging substrate can not be further reduced and hence the area of the flip-chip packaging substrate must be increased. On the other hand, through a semiconductor process, the silicon interposer 2 can have a line width below 3 um and a line pitch blow 3 um. Therefore, when the I/O number of the semiconductor chip 8 increases, the area of the silicon interposer 2 is sufficient to connect the semiconductor chip 8 having high I/O number without the need to increase the area of the packaging substrate 9.

In addition, the fine-line/fine-pitch characteristic of the silicon interposer 2 leads to short electrical transmission distance and high electrical transmission speed of the semiconductor chip 8.

FIGS. 2A to 2G are schematic cross-sectional views showing a fabrication method of the silicon interposer 2.

Referring to FIG. 2A, a silicon-containing substrate 20, i.e., a whole wafer, is provided, which has a first surface 20a with a plurality of recess holes 200 and a second surface 20b′ opposite to the first surface 20a.

Referring to FIG. 2B, an insulating layer 210 and a conductive post 211 are formed in each of the recess roles 200 so as to form a plurality of TSVs 21. Each of the TSVs 21 has a first end 21a exposed from the first surface 20a of the silicon-containing substrate 20 and a second end 21b opposite to the first end 21a.

Referring to FIG. 2C, an RDL structure 22 is formed on the first surface of the silicon-containing substrate 20 and electrically connected to the conductive posts 211. Further, a plurality of conductive elements 23 such as solder bumps are formed on the RDL structure 22.

Referring to FIG. 2D, the silicon-containing substrate 20 is disposed on a carrier 6 through the RDL structure 22 and a protective body 60 such as an adhesive layer is formed between the RDL structure 22 and the carrier 6. Then, a portion of the silicon-containing substrate 20 is removed from the second surface 20b′ thereof such that a second surface 20b is formed and flush with the second ends 21b of the TSVs 21.

Referring to FIG. 2E, a dielectric layer 24 is formed on the second surface 20b of the silicon-containing substrate 20 and a plurality openings 240 are formed in the dielectric layer 24 for exposing the second ends 21b of the TSVs 21.

Then, a conductive layer 25 made of Ti/Cu is formed on the dielectric layer 24 and the second ends 21b of the TSVs 21. Subsequently, a photoresist layer 26 is formed on the conductive layer 25 and patterned through exposure and development such that a plurality of open areas 260 to expose the second ends 21b of the TSVs 21.

Referring to FIG. 2F, a solder material 27 is formed on the second ends 21b of the TSVs 21 by electroplating.

Referring to FIG. 20, the photoresist layer 26 and the conductive layer 25 under the photoresist layer 26 are removed to form the silicon interposer 2.

Subsequently, the protective body 60 and the carrier 6 are removed. The solder material 27 is then reflowed to form solder bumps 27′ for bonding with a semiconductor chip 8. Further, a packaging substrate 9 can be mounted on the conductive elements 23.

However, the above-described processes for forming the solder material 27, such as forming the dielectric layer 24, forming and patterning the photoresist layer 26, electroplating the solder material 27, and removing the photoresist layer 26 and the conductive layer 25, are complicated and time-consuming and result in a high material cost.

Further, since the second ends of the conductive posts 211 must be completely exposed from the openings 240 of the dielectric layer 24 and the openings 240 must be completely exposed from the open areas 260, the open areas 260 are larger in size than the ends of the conductive posts 211. Therefore, the solder material 27 form on each of the second ends of the conductive posts 211 is larger in size than the second end of the conductive post 211. Furthermore, to prevent solder bridges from occurring, a certain pitch is required between the solder material 27. As such, the TSVs 21 cannot be connected to the electrode pads 80 having a smaller pitch.

Therefore, how to overcome the above-described drawbacks has become urgent.

### SUMMARY OF THE INVENTION

In view of the above-described drawbacks, the present invention provides a package structure, which comprises: an interposer having a first surface and a second surface opposite to the first surface; a plurality of conductive through holes formed in the interposer and penetrating the first and second surfaces, wherein each of the conductive through holes has a first end at the first surface of the interposer and a second end opposite to the first end; a plurality of conductive bumps in contact with the second ends of the conductive through holes and protruding from the second surface of the interposer; and at least a first external element mounted on the conductive bumps.

The present invention further provides a fabrication method of a package structure, which comprises the steps of: providing an interposer having a first surface with a plurality of recess holes and a second surface opposite to the first surface; forming a conductive bump in a lower portion of each of the recess holes; forming a conductive through hole on the conductive bump in each of the recess holes, wherein the conductive through hole has a first end at the first surface of the interposer and a second end opposite to the first end and in contact with the conductive bump; removing a portion of the interposer from the second surface thereof so as for the conductive bumps to protrude from the second surface of the interposer; and mounting at least a first external element on the conductive bumps.

In the above-described method, the conductive bumps can be formed by electroplating or deposition, and the conductive bumps can be made of a solder material.

In the above-described structure and method, the interposer can be a silicon-containing substrate and the conductive through holes can be through silicon vias (TSVs).

In the above-described structure and method, each of the conductive through holes can comprise a conductive post and an insulating layer formed between the conductive post and the interposer. The conductive post can be made of copper and formed by electroplating or deposition.

In an embodiment, after removing a portion of the interposer from the second surface thereof, the second ends of the conductive through holes protrude from the second surface of the interposer.

In the above-described structure and method, the first external element can be a semiconductor element, a semiconductor package module or a packaging substrate.

In the above-described structure and method, an RDL (Redistribution Layer) structure can be formed on the first surface of the interposer and electrically connected to the conductive through holes. Further, a second external element can be mounted on the RDL structure. The second external element can be a semiconductor element, a semiconductor package module or a packaging substrate.

Therefore, by forming conductive bumps in the recess holes and removing a portion of the interposer to expose the conductive bumps for a reflow process, the present invention dispenses with the conventional processes such as patterning, electroplating a solder material and removing the photoresist and conductive layer, thereby simplifying the fabrication process, shortening the process time and greatly reducing the material cost.

Further, since the conductive bumps are formed in the recess holes, the size of the conductive bumps is equal to or less than the size of the ends of the conductive through holes. Therefore, the pitch between the conductive bumps can be designed according to the pitch between the conductive through holes. Further, the conductive bumps are not limited by the size of openings in a dielectric layer as in the prior ar. Therefore, the present invention allows an external element having a smaller pitch contact pattern to be mounted on the conductive through holes and also prevents solder bridges and short circuits from occurring during the reflow process.

### BRIEF DESCRIPTION OF DRAWINGS

FIG. 1 is a schematic cross-sectional view of a conventional semiconductor package;

FIGS. 2A to 2G are schematic cross-sectional views showing a fabrication method of a silicon interposer according to the prior art; and

FIGS. 3A to 3F are schematic cross-sectional views showing a fabrication method of a package structure according to the present invention, wherein FIG. 3E′ shows another embodiment of FIG. 3E, and FIG. 3F′ shows another embodiment of FIG. 3F.

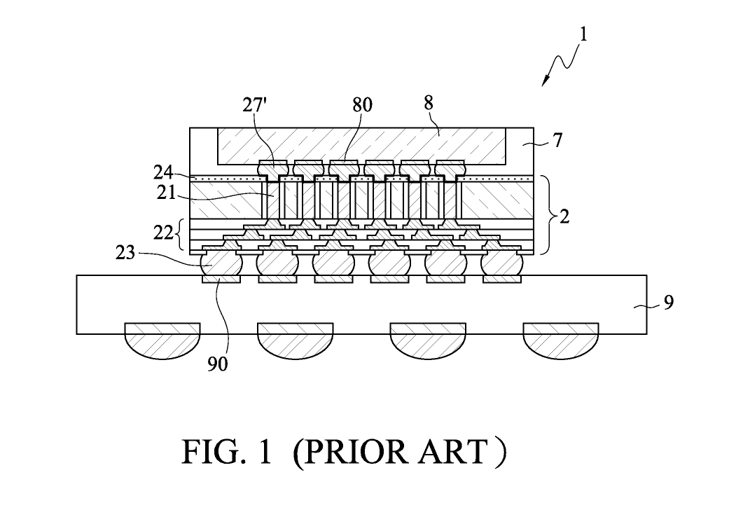

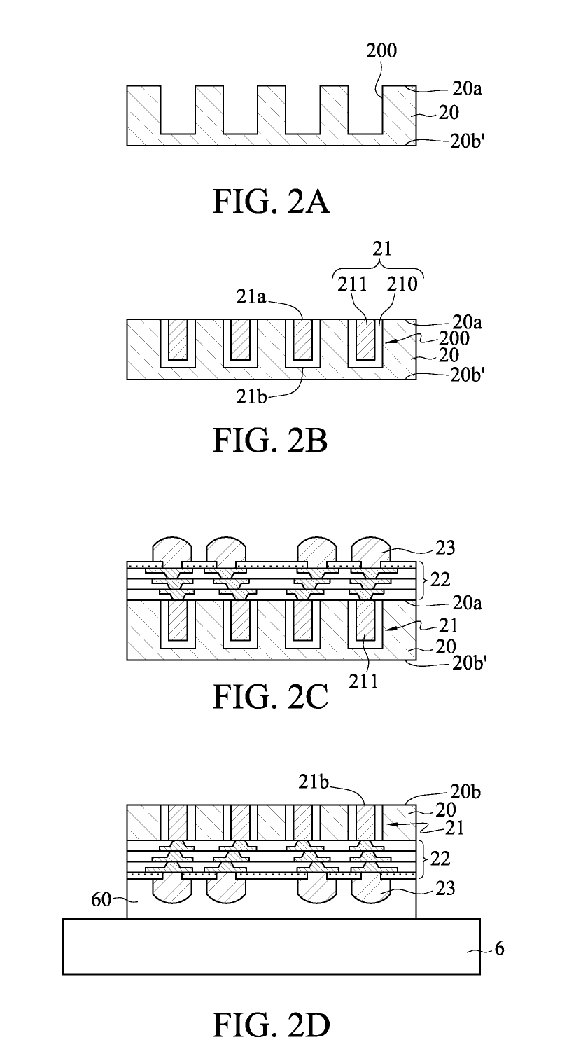

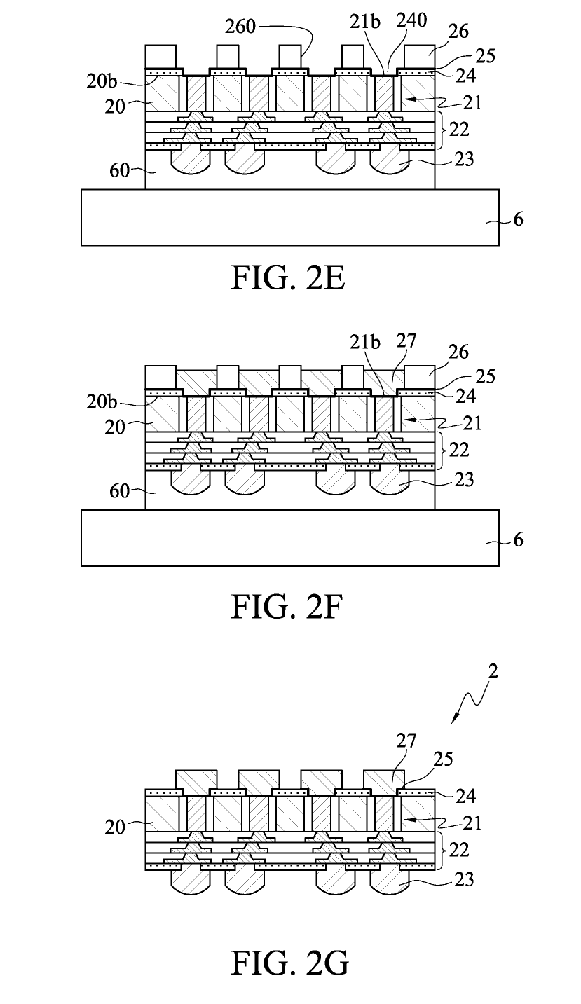

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “first”, “second”, “upper”, “lower”, “a” etc. are merely for illustrative purpose and should not be construed to limit the scope of the present invention.

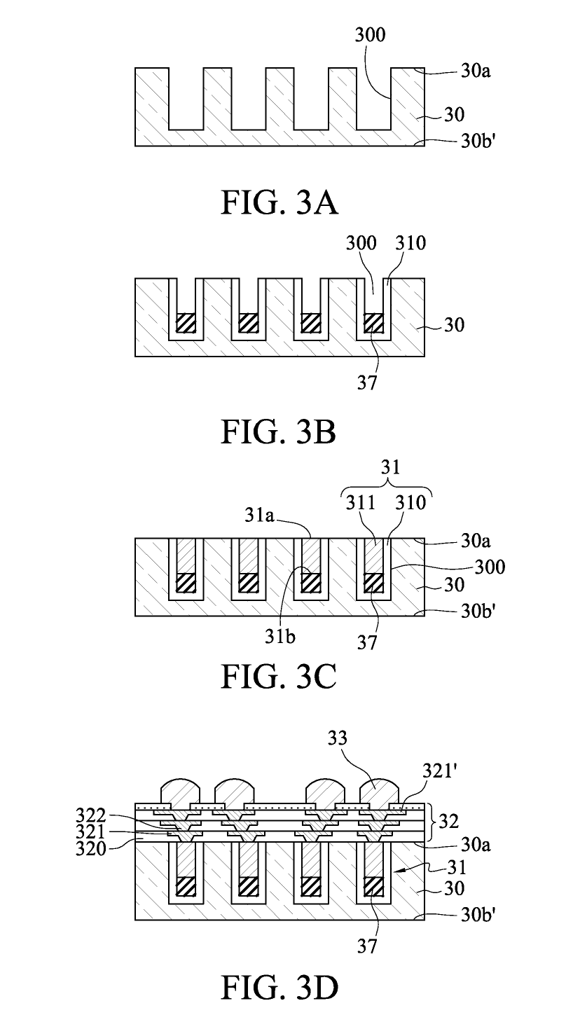

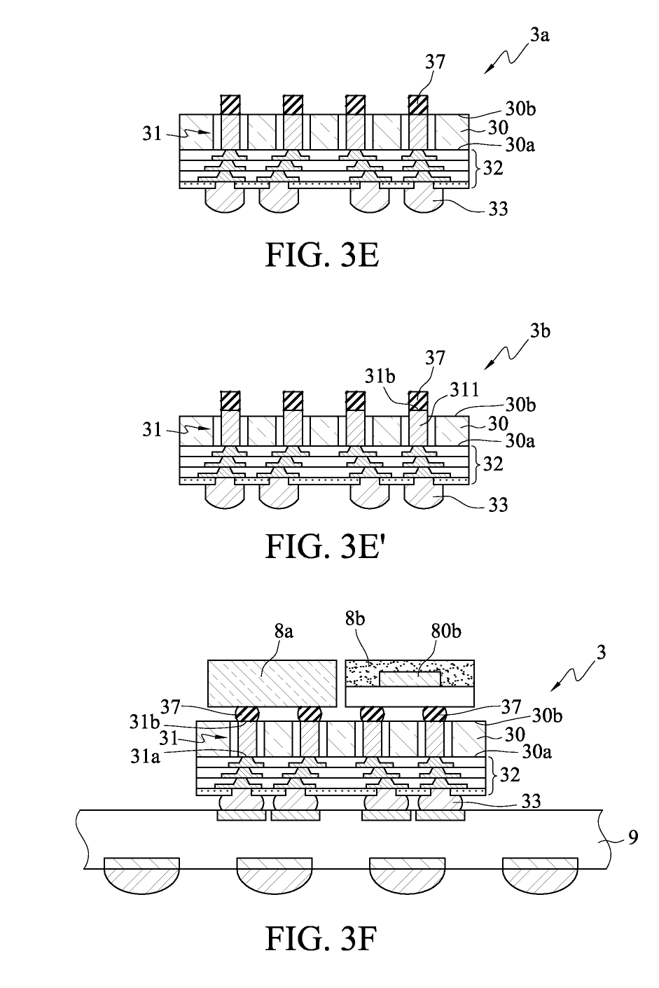

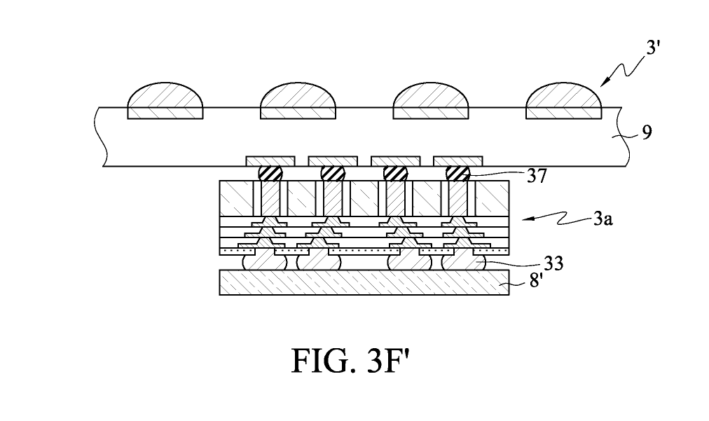

FIGS. 3A to 3F are schematic cross-sectional views showing a fabrication method of a package structure 3 according to the present invention.

Referring to FIGS. 3A, an interposer 30 is provided, which has a first surface 30a with a plurality of recess holes 300 and a second surface 30b′ opposite to the first surface 30a. The recess holes 300 do not penetrate the second surface 30b′.

In the present embodiment, the interposer 30 is a silicon-containing substrate.

Referring to FIG. 3B, an insulating layer 310 is formed on the wall and bottom of each of the recess holes 300, and then a conductive bump 37 is formed in a lower portion of each of the recess holes 300 by electroplating or deposition.

In the present embodiment, the insulating layer 310 is made of silicon dioxide and the conductive bump 37 is made of a solder material.

Referring to FIG. 3C, a conductive post 311 is formed on the conductive bump 37 in each of the recess holes 300 by electroplating or deposition. As such, the insulating layer 310 and the conductive post 311 form a conductive through hole such as a TSV 31. Each of the conductive through holes 31 has a first end 31a at the first surface 30a of the interposer 30 and a second end 31b opposite to the first end 31a and in contact with the conductive bump 37.

In the present embodiment, the conductive posts 311 are made of copper.

Referring to FIG. 3D, an RDL structure 32 is formed on the first surface 30a of the interposer 30 and electrically connected to the first ends 31a of the conductive through holes 31. i.e., the conductive posts 311. Further, a plurality of conductive elements 33 are formed on the RDL structure 32.

In the present embodiment, the RDL structure 32 has at least a dielectric layer 320, a circuit layer 321 formed on the dielectric layer 320 and a plurality of conductive vias 322 formed in the dielectric layer 320 and electrically connecting to the circuit layer 321. The conductive elements 33 are formed on the outermost circuit layer 321′.

The conductive elements 33 can be, but not limited to, metal bumps, metal posts, pin-shaped bodies, ball-shaped bodies.

Referring to FIG. 3E, by performing a thinning process, a portion of the interposer 30 is removed from the second surface 30b′ thereof such that a second surface 30b is formed and the conductive bumps 37 protrude from the second surface 30b. As such, a silicon interposer 3a is formed.

Referring to FIG. 3E′, in another embodiment, the second ends 31b of the conductive through holes 31, i.e., the conductive posts 311, protrude from the second surface 30b of the interposer 30 to serve as copper bumps and the conductive bumps 37 are reflowed to serve as an adhesive layer for mounting an external element on the conductive posts 311. As such, since the conductive posts 311 do not deform during the reflow process, the prevent invention avoids the risk of solder bridges and allows an external element with finer and denser contacts to be mounted on the conductive posts 37.

Referring to FIG. 3F, the conductive bumps 37 are reflowed and a plurality of first external elements are mounted on the conductive bumps 37, and the conductive elements 33 are reflowed and a second external element is mounted on the conductive elements 33.

In the present embodiment, a semiconductor element 8a such as a chip and a semiconductor package module 8b having a chip 80b are mounted on the conductive bumps 37, and a packaging substrate 9 is mounted on the conductive elements 33.

In another embodiment, referring to FIG. 3F′, a packaging substrate 9 is mounted on the conductive bumps 37 and a semiconductor element 8′ or a semiconductor package module (not shown) is mounted on the conductive elements 33.

The semiconductor element 8a, 8′ can be, but not limited to, an active component or a passive component.

According to the present invention, by forming the conductive bumps 37 in the recess holes 300 and removing a portion of the interposer to expose the conductive bumps 37 for a reflow process, the present invention dispenses with the conventional processes such as forming the dielectric layer 24, forming the conductive layer 25, forming and patterning the photoresist layer 26, electroplating the solder material 27, and removing the photoresist layer 26 and the conductive layer 25, thereby simplifying the fabrication process, shortening the process time and greatly reducing the material cost.

Further, since the conductive bumps 37 are formed in the recess holes 300, the size of the conductive bumps 37 is substantially equal to the size of the ends of the conductive posts 311, i.e., equal to or less than the size of the ends of the conductive through holes 31. Therefore, the pitch between the conductive bumps 37 can be designed according to the pitch between the recess holes 300 or the conductive through holes 31. Furthermore, the conductive bumps 37 are not limited by the size of openings of a dielectric layer as in the prior art. Therefore, the present invention allows an external element having a smaller pitch contact pattern to be mounted on the conductive through holes 31 and also prevents solder bridges and short circuits from occurring during the reflow process.

The present invention further provides a package structure 3, 3′, which has: an interposer 30 having a first surface 30a and a second surface 30b opposite to the first surface 30a; a plurality of conductive through holes 31 formed in the interposer 30 and penetrating the first and second surfaces 30a, 30b, wherein each of the conductive through holes 31 has a first end 31a at the first surface 30a of the interposer 30 and a second end 31b opposite to the first end 31a; a plurality of conductive bumps 37 in contact with the second ends 31b of the conductive through holes 31 and protruding from the second surface 30b of the interposer 30; and at least a first external element mounted on the conductive bumps 37.

In the present embodiment, the interposer 30 is a silicon-containing substrate and there is no dielectric layer formed on the second surface 30b of the interposer 30. The conductive through holes 31 are TSVs. Each of the conductive through holes 31 has a conductive post 311 made of such as copper and an insulating layer 310 formed between the conductive post 311 and the interposer 30. In an embodiment, the second ends 31b of the conductive through holes 31 protrude from the second surface 30b of the interposer 30.

In the present embodiment, the conductive bumps 37 are solder bumps.

In the present embodiment, the first external element is a semiconductor element 8a, 8′, a semiconductor package module 8b or a packaging substrate 9.

The package structure 3 can further have an RDL structure 32 formed on the first surface 30a of the interposer 30 and electrically connected to the first ends 31a of the conductive through holes 31. Further, a second external element can be mounted on the RDL structure 32. The second external element can be a semiconductor element 8a, 8′, a semiconductor package module 8b or a packaging substrate 9.

Therefore, by forming conductive bumps in the recess holes and removing a portion of the interposer to expose the conductive bumps for a reflow process, the present invention simplifies the fabrication process, shortens the process time and greatly reduces the material cost.

Further, since the conductive bumps are formed in the recess holes, the pitch between the conductive bumps can be designed according to the pitch between the conductive through holes, thereby allowing an external element having a smaller pitch contact pattern to be mounted on the conductive through holes and also preventing solder bridges and short circuits from occurring during the reflow process.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A package structure, comprising:
an interposer having a first surface and a second surface opposite to the first surface;
a plurality of conductive through holes formed in the interposer and penetrating the first and second surfaces, wherein each of the conductive through holes has a first end at the first surface of the interposer and a second end opposite to the first end;
a plurality of conductive bumps in contact with the second ends of the conductive through holes and protruding from the second surface of the interposer; and
at least a first external element mounted on the conductive bumps.

2. The structure of claim 1, wherein the interposer is a silicon-containing substrate.

3. The structure of claim 2, wherein the conductive through holes are through silicon vias (TSVs).

4. The structure of claim 1, wherein each of the conductive through holes comprises a conductive post and an insulating layer formed between the conductive post and the interposer.

5. The structure of claim 4, wherein the conductive posts are made of copper.

6. The structure of claim 1, wherein the second ends of the conductive through holes protrude from the second surface of the interposer.

7. The structure of claim 1, wherein the first external element is a semiconductor element, a semiconductor package module or a packaging substrate.

8. The structure of claim 1, further comprising an RDL (Redistribution Layer) structure formed on the first surface of the interposer and electrically connected to the conductive through holes.

9. The structure of claim 8, further comprising a second external element mounted on the RDL structure.

10. The structure of claim 9, wherein the second external element is a semiconductor element, a semiconductor package module or a packaging substrate.

11. A fabrication method of a package structure, comprising the steps of:
providing an interposer having a first surface with a plurality of recess holes and a second surface opposite to the first surface;
forming a conductive bump in a lower portion of each of the recess holes;
forming a conductive through hole on the conductive bump in each of the recess holes, wherein the conductive through hole has a first end at the first surface of the interposer and a second end opposite to the first end and in contact with the conductive bump;
removing a portion of the interposer from the second surface thereof so as for the conductive bumps to protrude from the second surface of the interposer; and
mounting at least a first external element on the conductive bumps.

12. The method of claim 11, wherein the interposer is a silicon-containing substrate.

13. The method of claim 12, wherein the conductive through holes are through silicon vias (TSVs).

14. The method of claim 11, wherein the conductive bumps are made of a solder material.

15. The method of claim 11, wherein the conductive bumps are formed by electroplating or deposition.

16. The method of claim 11, wherein each of the conductive through holes comprises a conductive post and an insulating layer formed between the conductive post and the interposer.

17. The method of claim 16, wherein the conductive posts are made of copper.

18. The method of claim 16, wherein the conductive posts are formed by electroplating or deposition.

19. The method of claim 11, wherein after removing a portion of the interposer from the second surface thereof, the second ends of the conductive through holes protrude from the second surface of the interposer.

20. The method of claim 11, wherein the first external element is a semiconductor element, a semiconductor package module or a packaging substrate.

21. The method of claim 11, further comprising forming on the first surface of the interposer an RDL (Redistribution Layer) structure electrically connected to the conductive through holes.

22. The method of claim 21, further comprising mounting a second external element on the RDL structure.

23. The method of claim 22, wherein the second external element is a semiconductor element, a semiconductor package module or a packaging substrate.
